(19) United States
(12) Patent Application Publication
(10) Pub. No.: US 2017/0200772 A1
(43) Pub. Date: Jul. 13, 2017

(54) SUBSTRATE AND METHOD OF MANUFACTURING PANEL

(71) Applicant: JOLED INC., Tokyo (JP)

(72) Inventor: Hidehiro YOSHIDA, Hyogo (JP)

(21) Appl. No.: 15/313,044

(22) PCT Filed: May 22, 2015
(86) PCT No.: PCT/JP2015/002604

§ 371 Date: Nov. 21, 2016

(30) Foreign Application Priority Data
May 27, 2014 (JP) 2014-108700

(51) Int. Cl. H01L 27/32; H01L 51/00

(52) U.S. Cl. CPC H01L 27/3218; H01L 27/3223; H01L 51/0005; H01L 27/3216; H01L 51/5012

(57) ABSTRACT

A substrate includes: a first panel region which includes a plurality of first cells disposed on the substrate which is a single substrate; a second panel region which includes a plurality of second cells disposed on the substrate and is different in size from the first panel region; a first dummy cell which has a same shape as a shape of the plurality of second cells and is disposed at a portion of an external surrounding area of the first panel region; and a second dummy cell which has a same shape as a shape of the plurality of first cells and is disposed at a portion of an external surrounding area of the second panel region.

### TECHNICAL FIELD

The present invention relates to a method of manufacturing a panel and a substrate used in the method of manufacturing the panel. In particular, the present invention relates to a method of manufacturing a panel using an ink-jet device, and a substrate used in the manufacturing of the panel.

### BACKGROUND ART

In recent years, much focus has been placed on a method of manufacturing an electronic device using an ink-jet technique.

Manufacturing with the ink-jet technique allows a simpler equipment constitution and lower costs, compared to an evaporation technique, etc. In addition, since the ink-jet technique is a direct patterning technique, a mask used in the evaporation technique is not required, allowing increase in size of a screen. For example, there has been an increasing market demand for a large-screen for electronic display devices, and expectations for the electron device manufacturing technique using ink-jet application has been increased.

One representative example is a method of forming an organic function layer, by discharging, using an ink-jet device, ink droplets including an organic function material onto a substrate (particularly, an organic electroluminescent (EL) display) which is to be a display substrate (see, for example, Patent Literature (PTL) 1).

Ink including the organic function material is applied to a color developing region arranged in a substrate. Here, the color developing region refers to a region in which any of sub pixels of red (R), green (G), and blue (B) are arranged. In other Words, in the substrate, at least three types of color developing regions (R, G, and B) are arranged parallel to each other in a particular direction

The following describes applying of ink to the color developing region with the ink-jet method, with reference to FIG. 6A and FIG. 6B.

FIG. 6A is a plan view of an ink-jet device. When an ink-jet head 10 passes above a substrate 12, ink is applied to a cell 13 on the substrate 12. A plurality of first panel regions 14 are disposed on the substrate 12, and cells 13 are disposed in the first panel region 14.

The substrate 12 is divided per the first panel region 14 to finally become a plurality of panels each corresponding to the first panel region 14. In other words, a large number of panels are manufactured at a time, by using a single substrate 12 including a plurality of first panel regions 14.

At this time, in the first panel regions 14, there is a difference in a dry condition of the applied ink between the cells 13 disposed in an outer position and the cells 13 disposed in an inner position.

This is due to the subsequent reason. The outer cells 13 each have no or less adjacent cell 13 at an outer position of the outer cells 13. For that reason, symmetric property differs between the outer position and the inner position centering around the outer cells 13 at the time of drying. As a result, ink shifts to one side among cells, leading to different ink dry conditions. In each of the first panel regions 14, ink deviates differently between the outer cells and the inner cells. In particular, the difference in ink deviation is large between the cells 13 on an upper side of the first panel region 14 and the cells 13 on the lower side of the first panel region 14, leading to non-uniformity when the first panel region 14 is turned on as a panel.

In this case, PTL 2 discloses arrangement illustrated in FIG. 6B. The diagram illustrated in FIG. 6B corresponds to the diagram illustrated in FIG. 6A. A first dummy cell 20 which does not emit light is disposed outside the first panel region 14, and ink is also applied to the first dummy cell 20. As a result, the environment becomes the same between the inner position and the outer position with respect to the outer cells 13. Accordingly, in the outer cells 13, the film thickness of the color developing material that is an organic function material becomes constant, and thus non-uniformity does not occur.

However, when a plurality of panel regions of different sizes are arranged on a single substrate 12 in order to increase material use efficiency of the substrate 12, a problem is posed as illustrated in FIG. 7A and FIG. 7B.

The diagram illustrated in FIG. 7A corresponds to the diagram illustrated in FIG. 6A. The first panel region 14 and the second panel region 15 having different sizes are disposed on the substrate 12. There are instances where the panels are arranged in this manner for using the substrate 12 with less interspace.

In this case, FIG. 7B illustrates an arrangement in which dummy cells are disposed in order to prevent non-uniformity due to dryness in the same manner as above. The diagram illustrated in FIG, 7B corresponds to the diagram illustrated in FIG. 7A. More specifically, the first dummy cells 20 and the second dummy cells 21 are disposed at the peripheries of the first panel region 14 and the second panel region 15, respectively.

### CITATION LIST

### Patent Literature

[PTL 1] Japanese Unexamined Patent Application Publication No. 2004-362818

[PTL 2] Japanese Patent Publication No. 3628997

### SUMMARY OF INVENTION

### Technical Problem

However, in the case of the diagram illustrated in FIG. 7B, the first dummy cells 20 and the second dummy cells 21 are disposed between the first panel region 14 and the second panel region 15. As a result, an extra area in which the first dummy cells 20 and the second dummy cells 21 are disposed is required, and thus the substrate 12 cannot be effectively used.

An object of the present invention is to provide a method of using a substrate effectively and avoiding non-uniformity as a panel, and the substrate, when a plurality of panel regions of different sizes are produced from a single substrate.

### Solution to Problem

According to an aspect of the present invention, a substrate is used which includes: a first panel region which has a tetragon shape and includes a plurality of first cells disposed on the substrate which is a single substrate; a second panel region which has a tetragon shape and includes a plurality of second cells disposed on the substrate, the second panel region being different in size from the first panel region; a first dummy cell which has a same shape as a shape of the plurality of second cells and is disposed at a portion of an external surrounding area of the first panel region, the portion corresponding to a side of the first panel region opposite from the second panel region adjacent to the first panel region; and a second dummy cell which has a same shape as a shape of the plurality of first cells and is disposed at a portion of an external surrounding area of the second panel region, the portion corresponding to a side of the second panel region opposite from the first panel region adjacent to the second panel region.

In addition, a method of manufacturing a panel is used. The method of manufacturing a panel includes: preparing a substrate which is a single substrate on which a first panel region and a second panel region are disposed, a first dummy cell having a same shape as a shape of a second cell in the second panel region is disposed at a portion of an external surrounding area of the first panel region, and a second dummy cell having a same shape as a shape of a first cell in the first panel region is disposed at a portion of an external surrounding area of the second panel region, the first panel region and the second panel region being different in size; applying ink to the first cell, the second cell, the first dummy cell, and the second dummy cell, with an ink-jet method; and drying the substrate.

### Advantageous Effects of Invention

According to the present invention, when a plurality of panels are manufactured from a single substrate, a shape of a dummy cell is varied in order to equalize the dry state at both ends of each of the panels. This allows the speed of drying at both ends of the panels to be equalized. In other words, the variation in drying as a panel is suppressed, and thus it is possible to form uniform panels without unevenness.

### BRIEF DESCRIPTION OF DRAWINGS

FIG. 1 is a plan view when ink is applied with an ink-jet method according to Embodiment 1.

FIG. 2 is an enlarged plan view schematically illustrating a substrate according to Embodiment 1, and the portions denoted by (a) to (c) correspond to different portions of the substrate.

FIG. 3 is a plan view when ink is applied with an ink-jet method according to Embodiment 2.

FIG. 4 is a plan view when ink is applied with an ink-jet method according to Embodiment 3.

FIG. 5 is an enlarged plan view schematically illustrating a substrate according to Embodiment 3, and the portions denoted by (a) to (C) correspond to different portions of the substrate.

FIG. 6 is a diagram collectively illustrating (a) a plan view when ink is applied with a conventional ink-jet method and (b) a plan view of a conventional substrate, and the portion denoted by (a) corresponds to the plan view when ink is applied with the conventional ink-jet method and the portion denoted by (b) corresponds to the plan view of the conventional substrate.

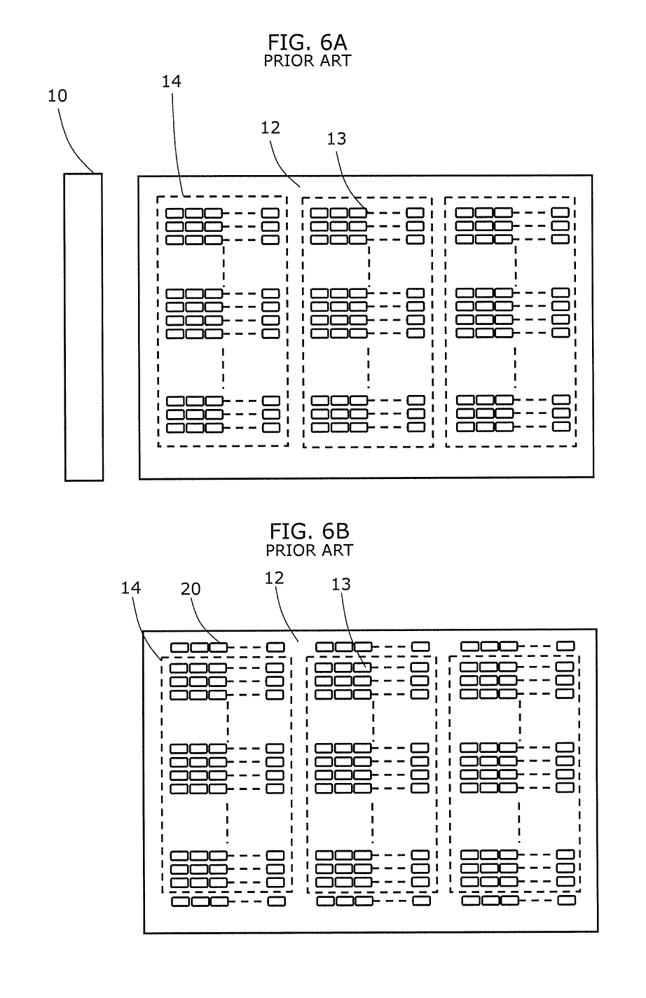

FIG. 7 is a plan view when ink is applied with a plurality of conventional ink-jet methods.

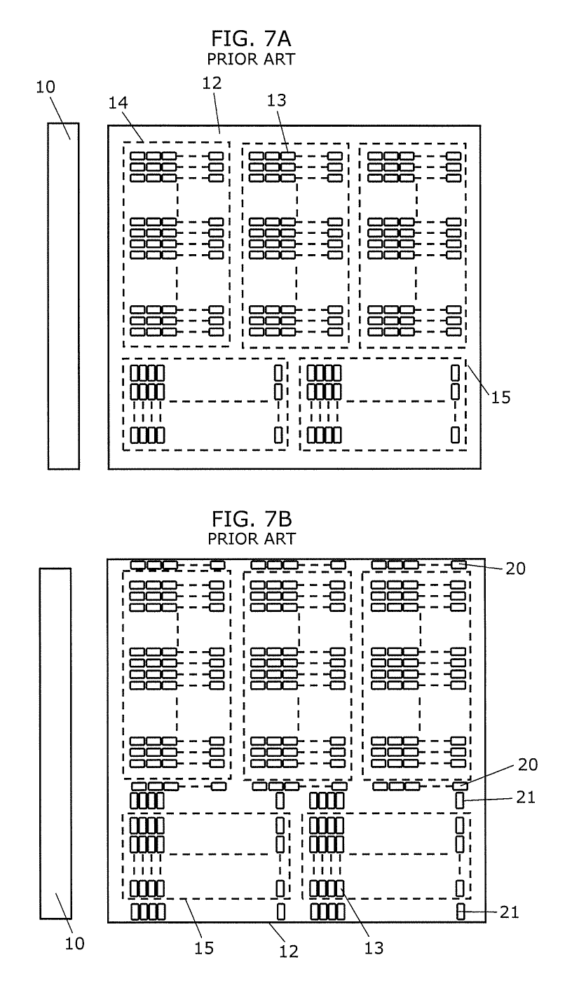

### DESCRIPTION OF EMBODIMENTS

Hereinafter, embodiments of the present invention will be described with reference to the drawings. It should be noted that the embodiments described below are mere examples of a substrate and a method of manufacturing a panel according to the present invention. As such, the scope of the present invention is demarcated by the recitations in the Claims using the below embodiment as a reference, and is not intended to be limited merely by the following embodiments. Therefore, among the structural elements in the following exemplary embodiments, structural elements not recited in any one of the independent claims which represent the most generic concepts are described as structural elements not indispensable for achieving the object of the present invention but included for more preferred configuration.

The Drawings are schematic illustrations in which emphasis, omission, adjustment in proportion are made as appropriate to illustrate the present invention, and may differ from the actual shape, positional relationship, and proportion.

### Embodiment 1

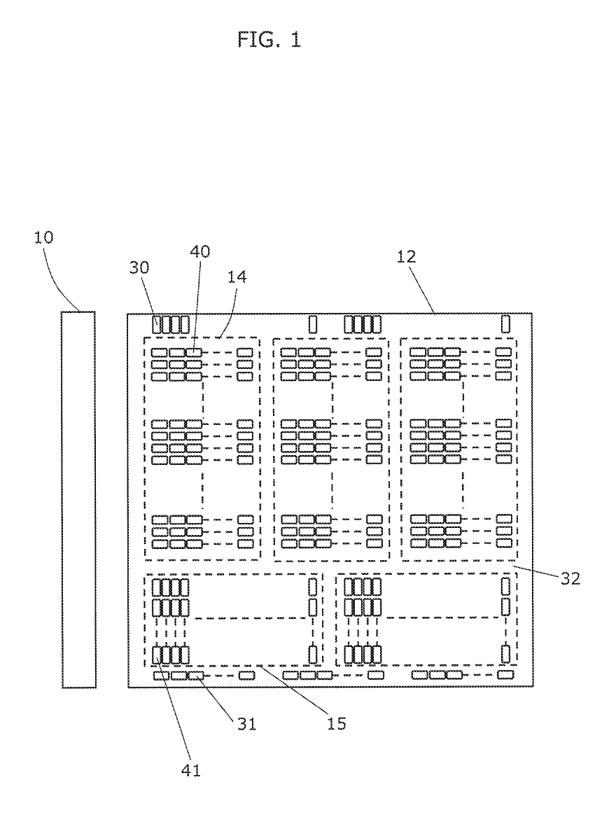

FIG. 1 illustrates a plan view of a substrate 12 according to Embodiment 1. A first panel region 14 and a second panel region 15 having different sizes (hereinafter also collectively referred to as “panel region”) are disposed on a single substrate 12. In addition, a first dummy cell 30 and a second dummy cell 31 are disposed at a portion of an external surrounding area of the first panel region 14 and a portion of an external surrounding area of the second panel region 15, respectively. However, a dummy cell is not disposed in an inter-panel region 32

The substrate 12 is a glass substrate according to the present embodiment. In addition, a plurality of first panel regions 14 and a plurality of second panel regions are included in a single substrate 12, and a plurality of panels are manufactured by cutting out each of the panel regions from the substrate 12. An organic EL display panel is assumed as the panel manufactured from the substrate 12. It should be noted that the panels are to be included in products such as other displays and devices.

Here, the portion of an external surrounding area refers to the circumferential area of the panel region not including the inside of the panel region. In addition, the cell is a section occupying a portion of the panel region, and having one function when finalized as an end product. In the case of the present embodiment, the panel is an organic EL display panel, and the cell corresponds to a sub pixel. In addition, there are instances where the cell is enclosed by or interposed between banks.

Here, the first dummy cell 30 has the same shape as or a similar shape to not the first cell 40 of the first panel region 14 but the shape of the second cell 41 of the second panel region 15. In addition, the second dummy cell 31 has the same shape as or a similar shape to the shape of not the second cell 41 of the second panel region 15 but the shape of the first cell 40 of the first panel region 14.

Furthermore, the first dummy cell 30 is oriented in the same direction as the second cell 41 of the second panel region 15, and the second dummy cell 31 is oriented in the same direction as the first cell 40 of the first panel region 14.

In addition, a gap between the first dummy cell 30 and the first cell 40 adjacent to the first dummy cell 30 is equivalent to a gap between the first cell 40 adjacent to the second panel region 15 adjacent to the first panel region 14 and the second cell 41 adjacent to the first cell 40.

With such a configuration, the first dummy cell 30 and the second cell 41. are located outside the first panel region 14 and at different ends in a predetermined first direction (the vertical direction in FIG. 1, and a longitudinal direction of the first panel region 14). The first dummy cell 30 and the second cell 41 have the same or similar shapes. In addition, in the case of the present embodiment, the first dummy cell 30 and the second cell 41 are axisymmetric about an axis virtually passes the first panel region 14. As a result, geometric symmetry of the first panel region 14 to which the first dummy cell 30 and the second cell 41 are added improves, the ink applied to each of the first cells 40 in the first panel region 14 is dried uniformly, and thus non-uniformity does not occur.

In the same manner, the second dummy cell 31 and the first cell 49 are located outside the second panel region 15 and at different ends in a predetermined first direction (the vertical direction in FIG. 1, and a crosswise direction of the second panel region 15). The second dummy cell 31 and the first cell 40 have the same or similar shapes. In addition, in the case of the present embodiment, the second dummy cell 31 and the first cell 40 are axisymmetric about an axis virtually passes the second panel region 15. As a result, geometric symmetry of the second panel region 15 to which the second dummy cell 31 and the first cell 40 are added improves, the ink applied to each of the second cells 41 in the second panel region 15 is dried uniformly, and thus non-uniformity does not occur.

In general, when a plurality of panel regions of different sizes are provided as described above, the longitudinal direction of each of the panel regions is often arranged vertically in order to effectively use the substrate 12. In addition, each cell included in each of the panel region is often shaped into a rectangle. Accordingly, the longitudinal direction of the rectangle of each of the first dummy cell 30 and the first cell 40 is vertical. In the same manner, the longitudinal direction of the rectangle of each of the second dummy cell 31 and the second cell 41 is also vertical.

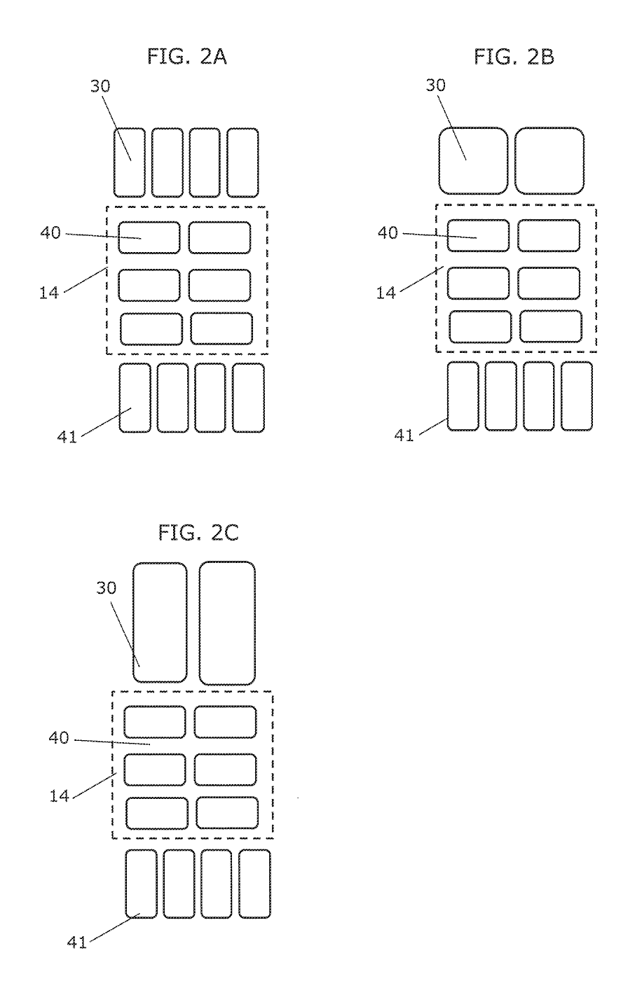

Here, a modification example shall be described using examples illustrated in FIG. 2A to FIG. 2C in each of which the first panel region 14 is partially enlarged and simplified.

In FIG. 2A, first dummy cells 30 having the same shape are provided outside the first panel region 14 and at one side of a predetermined first direction (the vertical direction in FIG. 2A) and the second cells 41 are provided at the other side. In this manner, since the environment becomes the same between the both end portions of the first cell 40 in the predetermined first direction, ink is dried uniformly, and thus non-uniformity does not occur.

In FIG. 2B, the first dummy cells 30 each having a shape different from the first dummy cell 30 illustrated in FIG. 2A are illustrated. More specifically, the first dummy cells 30 each have a shape resulting from combining two second cells 41 into one. Here, combining two second cells 41 into one means that the first dummy cell 30 has the same shape as the smallest tetragon including two adjacent second cells 41.

In FIG. 2C, the first dummy cells 30 each having a shape different from the first dummy cells 30 illustrated in FIG. 2A are illustrated. More specifically, the first dummy cells 30 illustrated in FIG. 2C each have a shape similar to the shape of the second cell 41.

As a result, the first cells 40 disposed at both ends of the first panel region 14 in a predetermined first direction (for example, the direction along one side of the substrate 12) are allowed to be dried in a similar environment, and thus non-uniformity does not occur due to the cells disposed at vertical ends. In addition, an equivalent function effect can be obtained also in the second panel region 15, by providing the second dummy cell 31 in the same manner as the first panel region 14.

### Embodiment 2

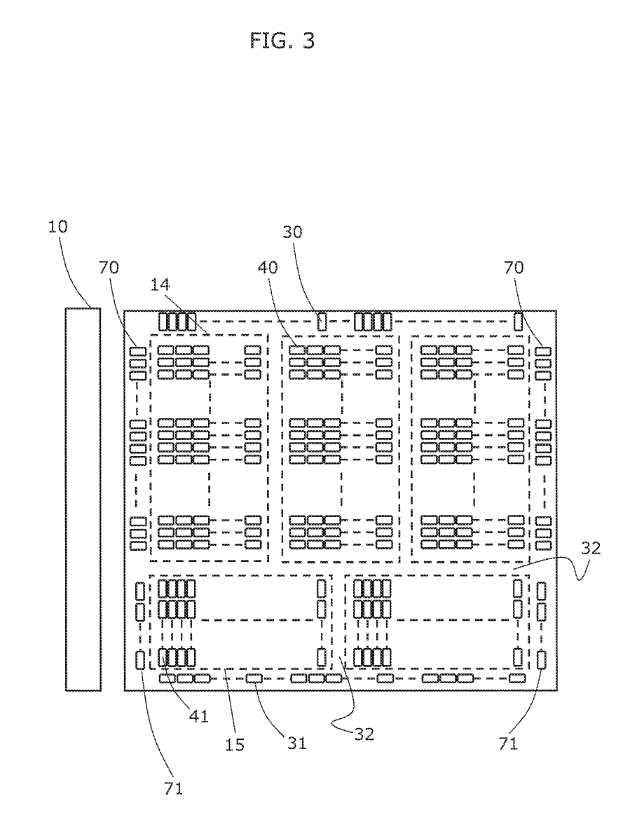

Embodiment 2 shall be described with reference to FIG. 3.

FIG. 3 is a diagram which corresponds to FIG. 1. FIG. 3 illustrates an arrangement which is different from the arrangement of the substrate 12 illustrated in FIG. 1, in that third dummy cells 70 and fourth dummy cells 71 are disposed outside the first panel region 14 and the second panel region 15 and at both ends in the second direction (i.e., the horizontal direction in FIG. 3) intersecting (i.e., being orthogonal to) the first direction.

The third dummy cell 70 has the same shape as the first cell 40. The fourth dummy cell 71 has the same shape as the second cell 41.

As a result, the both ends in the second direction of each of the first panel region 14 and the second panel region have the same environment at the time of drying, and thus non-uniformity does not occur due to the cells disposed at both ends in the second direction in the panel region.

### Embodiment 3

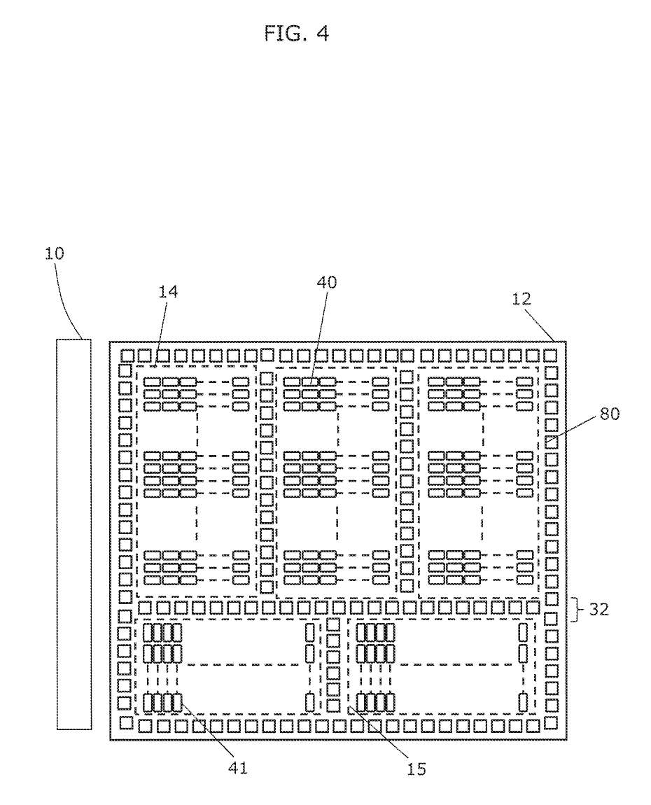

Embodiment 3 shall be described with reference to FIG. 4. FIG. 4 is a diagram which corresponds to FIG. 1 and FIG. 3. FIG. 4 is different from FIG. 1 and FIG. 3 in that dummy cells of one type are provided, and the dummy cells are provided also in the inter-panel region 32.

In the case of the present embodiment, fifth dummy cells 80 are disposed at the entire external surrounding areas of the first panel region 14 and the second panel region 15. The shape of the fifth dummy cell 80 is different from the shape of the first cell 40 and the second cell 41. The shape of the fifth dummy cell 80 is a combination of the first cell 40 and the second cell 41.

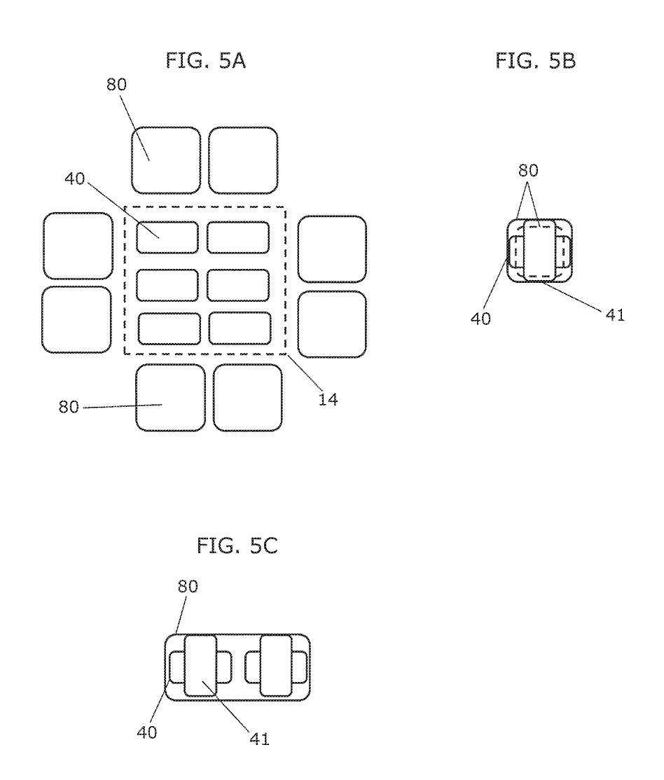

The following describes the details with reference to FIG. 5A to FIG. 5C. FIG. 5A illustrates a partially enlarged and simplified portion illustrated in FIG. 4, The fifth dummy cells 80 are provided around the first panel region 14. Since the same dummy cells are disposed at the portion of an external surrounding area corresponding to the both ends in the first direction that is the longitudinal direction of the first panel region 14 and at the portion of an external surrounding area corresponding to the both ends in the second direction that is the crosswise direction of the first panel region 14, good symmetric property is obtained, and thus non-uniformity does not occur.

Unlike Embodiments 1 and 2, the fifth dummy cells 80 here are provided also in the inter-panel region 32. This is for providing a more effect on the panel region, because the shape of the fifth dummy cell 80 is different from the shapes of the first cell 40 and the second cell 41.

The following describes the shape of the fifth dummy cell 80 with reference to FIG. 5B. FIG. 5B is a plan view when the first cell and the second cell 41 are virtually stacked, The fifth dummy cell 80 has a shape of a combination of the first cell 40 and the second cell 41. The fifth dummy cell 80 has the same shape as or a similar shape to the smallest tetragon capable of including the first cell 40 and the second cell 41 virtually stacked with the centers being matched.

The first cell 40 and the second cell 41 are each rectangular, the longitudinal direction is perpendicular to each other, and mostly the length of the longitudinal direction is equivalent. For that reason, it is preferable that the fifth dummy cell 80 is square.

The fifth dummy cell 80 is formed into a tetragon for facilitating ink application.

The fifth dummy cell 80 is disposed at the external surrounding area in order to provide a more effect than the first cell 40 and the second cell 41.

However, it should be noted that the size of the fifth dummy cell 80 needs to be greater than or equal to an area of the first cell 40 and the second cell 41 virtually stacked with the centers being matched. The smallest size is illustrated in FIG. 5B by a portion indicated by a dashed line.

It should be noted that, as illustrated in FIG. 5C, the fifth dummy cell 80 may have a shape resulting from combining two adjacent ones of a set of the first cell 40 and the second cell 41 virtually stacked with the centers being matched.

As a result, the first panel region 14 and the second panel region 15 have the same environment at both horizontal ends, and thus non-uniformity does not occur due to the cells at the horizontals ends.

Non-uniformity is prevented by providing only one line of the fifth dummy cells in the inter-panel region 32.

### Others

It should be noted that the present invention is not limited to the foregoing embodiments. Although only an exemplary embodiment of the present invention has been described in detail above, those skilled in the art will readily appreciate that many modifications are possible in the exemplary embodiment without materially departing from the novel teachings and advantages of the present invention. Accordingly, all such modifications are intended to be included within the scope of the present invention.

For example, the substrate may include: a first panel region which has a tetragon shape and includes a plurality of first cells disposed on the substrate which is a single substrate; a second panel region which has a tetragon shape and includes a plurality of second cells disposed on the substrate, the second panel region being different in size from the first panel region; a first dummy cell which has a same shape as a shape of the plurality of second cells and is disposed at a portion of an external surrounding area of the first panel region, the portion corresponding to a side of the first panel region; and a second dummy cell which has a same shape as a shape of the plurality of first cells and is disposed at a portion of an external surrounding area of the second panel region, the portion corresponding to a side of the second panel region.

In addition, the substrate may include a third dummy cell which has a same shape as the shape of the plurality of first cells and is disposed at the portion of an external surrounding area of the first panel region, the portion corresponding to another side adjacent to the side of the first panel region; and a fourth dummy cell which has a same shape as the shape of the plurality of third cells, and is disposed at the portion of an external surrounding area of the second panel region, the portion corresponding to another side adjacent to the side of the second panel region.

In addition, the substrate may be the substrate in which a dummy cell is not be disposed between the first panel region and the second panel region.

In addition, in the substrate, the plurality of first cells, the plurality of second cells, the first dummy cell, the second dummy cell may each be rectangular, a longitudinal direction of the plurality of first cells and a longitudinal direction of the first dummy cell may be perpendicular to each other, and a longitudinal direction of the rectangular shapes of the plurality of second cells and the second dummy cell may be perpendicular to each other.

In addition, the substrate may include: a first panel region which has a tetragon shape and includes a plurality of first cells each being rectangular and disposed on the substrate which is a single substrate; a second panel region which has a tetragon shape and includes a plurality of second cells each being rectangular and disposed on the substrate, the second panel region being different in size from the first panel region; and a fifth dummy cell which is square and disposed at a portion of an external surrounding area of the first panel region and at a portion of an external surrounding area of the second panel region.

In addition, in the substrate, the first panel region and the second panel region may each be rectangular, and a longitudinal direction of the rectangular shapes of the first panel region and the first panel region may be perpendicular to each other.

In addition, a method of manufacturing a panel may include: preparing a substrate which is a single substrate on which a first panel region and a second panel region are disposed adjacently, a first dummy cell having a same shape as a shape of a second cell in the second panel region is disposed at a portion of an external surrounding area of the first panel region which corresponds to a side of the first panel region, and a second dummy cell having a same shape as a shape of a first cell in the first panel region is disposed at a portion of an external surrounding area of the second panel region which corresponds to a side of the second panel region, the first panel region and the second panel region being different in size; applying ink to the first cell, the second cell, the first dummy cell, and the second dummy cell, with an ink-jet method; and drying the substrate.

In addition, the method of manufacturing a panel may include: providing a third dummy cell having a same shape as the shape of the first cell, on a side of the first panel region which is non-adjacent to the second panel region; and providing a fourth dummy cell having a same shape as a shape of the second cell, on a side of the second panel region which is non-adjacent to the first panel region.

In addition, a method of manufacturing a panel may include: preparing a substrate which is a single substrate on which a first panel region and a second panel region are disposed adjacently, and a fifth dummy cell is disposed on each side of a portion of an external surrounding area of the first panel region and a portion of an external surrounding area of the second panel region, the first panel region and the second panel region being different in size; applying ink to a first cell in the first panel region, a second cell in the second panel region, and the fifth dummy cell, with an ink-jet method; and drying the substrate. The fifth dummy cell may have a shape resulting from combining a shape of the first cell and a shape of the second cell.

In addition, the substrate 12 may include cells according to the above-described embodiment, which are different between the vertical direction of the substrate 12 and the horizontal direction of the substrate 12.

### Advantageous Effect

According to the above-described method, when ink is applied, with ink-jet application, to panel regions of different orientations disposed on a substrate, dummy cells are patterned such that the first direction and the second direction (horizontal and vertical directions) of the panel regions are symmetrical, and thus it is possible to obtain, after the ink is applied, film thickness distribution of a function layer of which the first direction and the second direction (horizontal and vertical directions) are symmetrical.

With such symmetric formation as described above, it is possible to provide a panel with less streak unevenness, making it possible to achieve high yield.

### INDUSTRIAL APPLICABILITY

The method according to the present invention is applicable to manufacturing of a plurality of devices and displays from a substrate,

### REFERENCE SIGNS LIST

10 ink-jet head

12 substrate

13 cell

14 first panel region

15 second panel region

20 first dummy cell

21 second dummy cell

30 first dummy cell

31 second dummy cell

32 inter-panel region

40 first cell

41 second cell

70 third dummy cell

71 fourth dummy cell

80 fifth dummy cell

1. A substrate, comprising:
a first panel region which has a tetragon shape and includes a plurality of first cells disposed on the substrate which is a single substrate;
a second panel region which has a tetragon shape and includes a plurality of second cells disposed on the substrate, the second panel region being different in size from the first panel region;
a first dummy cell which has a same shape as a shape of the plurality of second cells and is disposed at a portion of an external surrounding area of the first panel region, the portion corresponding to a side of the first panel region opposite from the second panel region adjacent to the first panel region; and
a second dummy cell which has a same shape as a shape of the plurality of first cells and is disposed at a portion of an external surrounding area of the second panel region, the portion corresponding to a side of the second panel region opposite from the first panel region adjacent to the second panel region.

2. The substrate according to claim 1, comprising:
a third dummy cell which has a same shape as the shape of the plurality of first cells and is disposed at a portion of an external surrounding area of the first panel region, the portion corresponding to a side of the first panel region, the side being adjacent to the side on which the first dummy cell is disposed; and
a fourth dummy cell which has a same shape as the shape of the plurality of second cells, and is disposed at a portion of an external surrounding area of the second panel region, the portion corresponding to a side of the second panel region, the side being adjacent to the side on which the second dummy cell is disposed.

3. The substrate according to claim 1, wherein
a dummy cell is not disposed between the first panel region and the second panel region.

4. The substrate according to claim 1, wherein
the plurality of first cells, the plurality of second cells, the first dummy cell, and the second dummy cell are each rectangular,
a longitudinal direction of the plurality of first cells and a longitudinal direction of the first dummy cell are perpendicular to each other, and
a longitudinal direction of the plurality of second cells and a longitudinal direction of the second dummy cell are perpendicular to each other.

5. A substrate, comprising:
a first panel region which has a tetragon shape and includes a plurality of first cells each being rectangular and disposed on the substrate which is a single substrate;
a second panel region which has a tetragon shape and includes a plurality of second cells each being rectangular and disposed on the substrate, the second panel region being different in size from the first panel region; and
a fifth dummy cell which is square and disposed at a portion of an external surrounding area of the first panel region and at a portion of an external surrounding area of the second panel region.

6. The substrate according to claim 1, wherein
the first panel region and the second panel region are each rectangular, and a longitudinal direction of the first panel region and a longitudinal direction of the second panel region are perpendicular to each other.

7. A method of manufacturing a panel, the method comprising:
preparing a substrate which is a single substrate on which a first panel region and a second panel region are disposed, a first dummy cell having a same shape as a shape of a second cell in the second panel region is disposed at a portion of an external surrounding area of the first panel region, and a second dummy cell having a same shape as a shape of a first cell in the first panel region is disposed at a portion of an external surrounding area of the second panel region, the first panel region and the second panel region being different in size;
applying ink to the first cell, the second cell, the first dummy cell, and the second dummy cell, with an ink-jet method; and
drying the substrate.

8. The method of manufacturing a panel according to claim 7, the method comprising:
providing a third dummy cell having a same shape as the shape of the first cell, at a portion of an external surrounding area of the first panel region, the portion being non-adjacent to the second panel region; and
providing a fourth dummy cell having a same shape as a shape of the second cell, at a portion of an external surrounding area of the second panel region, the portion being non-adjacent to the first panel region.

9. A method of manufacturing a panel, the method comprising:
preparing a substrate which is a single substrate on which a first panel region and a second panel region are disposed adjacently, and a fifth dummy cell is disposed at a portion of an external surrounding area of the first panel region and at a portion of an external surrounding area of the second panel region, the first panel region and the second panel region being different in size;
applying ink to a first cell in the first panel region, a second cell in the second panel region, and the fifth dummy cell, with an ink-jet method; and
drying the substrate, wherein
the fifth dummy cell has a shape resulting from combining a shape of the first cell and a shape of the second cell.

10. The substrate according to claim 5, wherein
the first panel region and the second panel region are each rectangular, and
a longitudinal direction of the first panel region and a longitudinal direction of the second panel region are perpendicular to each other.
